(19) United States
(12) Patent Application Publication
(10) Pub. No.: US 2013/0081681 A1
(43) Pub. Date: Apr. 4, 2013

(54) PHOTOVOLTAIC DEVICE

(71) Applicants: Chien-Ming WU, Hsinchu (TW); Wu-Tsung LO, Hsinchu (TW)

(72) Inventors: Chien-Ming WU, Hsinchu (TW); Wu-Tsung LO, Hsinchu (TW)

(73) Assignee: Epistar Corporation, Hsinchu (TW)

(21) Appl. No.: 13/251,453

(22) Filed: Oct. 3, 2011

(51) Int. Cl. H01L 31/06

(52) U.S. Cl. 136/255

(57) ABSTRACT

This disclosure discloses a light-emitting device. The light-emitting device comprises a substrate; a first photovoltaic cell disposed over the substrate comprising a base layer having a first conductivity type; an emitter layer having a second conductivity type; a window layer having the second conductivity type; an intermediate structure between the emitter layer and the window layer having the second conductivity type, and comprising a first portion adjacent to the emitter layer and a second portion on the first portion. The first portion comprises a bandgap energy higher than that of the emitter layer and the intermediate structure is substantially lattice matched with the emitter layer.

### BACKGROUND

1. Technical Field

The present disclosure relates to a photovoltaic device, and in particular to a photovoltaic device with an intermediate layer having a graded bandgap energy.

2. Description of the Related Art

In recent years, energy shortage has attracted people's attention on the importance of saving energy and environmental protection. Thus, many researches focus on alternative energy and renewable energy. Solar power is found to be one of the competitive alternatives for conventional energy. The main reason is that solar cell can convert sun light into electricity without generating any polluting gas such as carbon dioxide (CO₂) and can ease the phenomenon of global warming problem.

Compared to a solar cell comprising a single cell, tandem solar cells comprising a plurality of solar cells stacked on each other have a higher efficiency. However, how to increase an efficiency of the solar cell is still an important issue in this art.

### SUMMARY OF THE DISCLOSURE

The present disclosure provides a photovoltaic device.

The photovoltaic device comprises: a substrate; a first photovoltaic cell disposed over the substrate comprising a base layer having a first conductivity type; an emitter layer having a second conductivity type; a window layer having the second conductivity type; an intermediate structure between the emitter layer and the window layer having the second conductivity type, and comprising a first portion adjacent to the emitter layer and a second portion on the first portion. The first portion comprises a bandgap energy higher than that of the emitter layer and the intermediate structure is substantially lattice matched with the emitter layer.

### BRIEF DESCRIPTION OF THE DRAWING

The accompanying drawing is included to provide easy understanding of the application, and is incorporated herein and constitutes a part of this specification. The drawing illustrates the embodiment of the application and, together with the description, serves to illustrate the principles of the application.

FIG. 1 is a cross-sectional view of a photovoltaic device in accordance with the present disclosure.

### DETAILED DESCRIPTION OF THE EMBODIMENTS

The following shows the description of one embodiment of the present disclosure in accordance with the drawing.

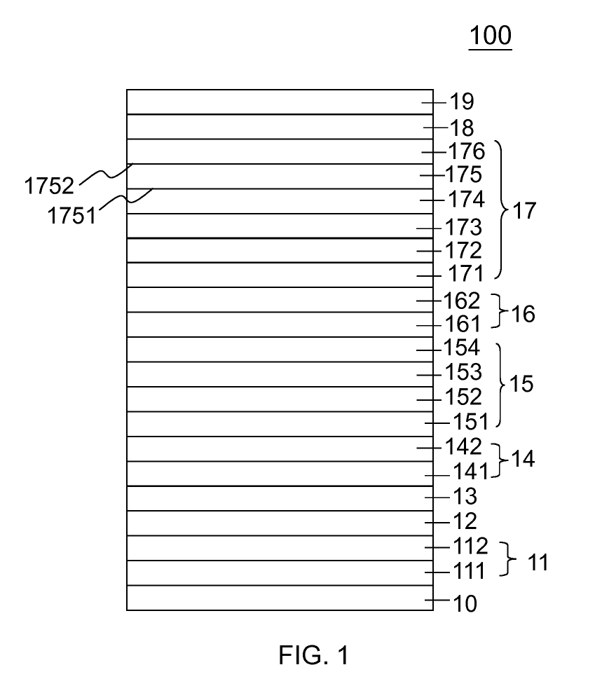

FIG. 1 discloses a photovoltaic device 100 according to one embodiment of the present disclosure. The photovoltaic device 100 comprises a first, second, and third photovoltaic cells 17, 15, 11. The third photovoltaic cell 11 also acts as a substrate on which the first and second photovoltaic cells 17, 15 disposed and stacked. A first tunnel junction 16 is formed between the first and the second photovoltaic cells 17, 15, and a second tunnel junction 14 is formed between the second and the third photovoltaic cells 15, 11. A nucleation layer 12 is formed on the third photovoltaic cell 11, and the buffer layer 13 is formed on the nucleation layer 12. The photovoltaic device 100 further comprises a first contact layer 18 formed on the first photovoltaic cell 17, an anti-reflecting coating (ARC) layer 19 formed on the contact layer 18, and a second contact layer 10 formed on the third photovoltaic cell 11. The first photovoltaic cell 17 is the top cell for receiving solar energy, the third photovoltaic cell 11 is the bottom cell and the second photovoltaic cell 15 is the middle cell and sandwiched between the first and third photovoltaic cells 17, 11.

In this embodiment, the first photovoltaic cell 17 comprises a back-surface field (BSF) layer 171, a base layer 172 having a first conductivity type, an i-type semiconductor layer 173, an emitter layer 174 having a second conductivity type, a window layer 176 having the second conductivity type, and an intermediate structure 175 having the second conductivity type and sandwiched between the emitter layer 174 and the window layer 176. The intermediate structure 175 has a first portion 1751 adjacent to and directly contacting the emitter layer 174, and a second portion 1752 on the first portion 1751. In this embodiment, the second portion 1752 is adjacent to and directly contacting the window layer 176. The first and second conductivity types are formed by doping impurities in these layers (the base layer, the window layer, the emitter layer, the intermediate layer). When the impurity is Si, S or Te, the conductivity type is n-type. When the impurity is Zn, Mg, C or Be, the conductivity type is p-type. In this embodiment, the first conductivity type is p-type, and the second conductivity type n-type. In addition, a concentration of the impurity of the intermediate structure 175 is higher than that of the window layer 176. The concentration of the impurity in each of the intermediate structure 175 and the window layer 176 ranges from 6.1×10″ cm⁻³ to 8.2×10¹⁸ cm⁻³.

The intermediate structure 175 is substantially lattice matched with the emitter layer 174. In addition, the intermediate structure 175 is also substantially lattice matched with the window layer 176. It is noted that “substantially lattice matched” means that the difference in the lattice constant between the emitter layer 174 and the intermediate structure 175 or between the intermediate structure 175 and the window layer 176 is less than 5%, preferably, less than 2%. Moreover, the window layer 176 has a bandgap energy higher than that of the emitter layer 174, and the intermediate structure 175 has a bandgap energy between that of the emitter layer 174 and the window layer 176. The first portion 1751 of the intermediate layer 175 comprises a bandgap higher than that of the emitter layer, and the second portion 1752 of the intermediate layer 175 comprises a bandgap higher than that of the first portion 1751. In one embodiment, the intermediate structure 175 has a graded bandgap energy increasing along a direction from the emitter layer 174 to the window layer 176. The intermediate structure 175 comprises In_{0.5}(GaₓAl₁₋ₓ)_{0.5}P, 0≦x<1; preferably, 0≦x≦0.25. The x in In_{0.5}(GaₓAl₁₋ₓ)_{0.5}P is stepped or continuously variant from the first portion 1751 to the second portion 1752. When the intermediate structure 175 is a single layer, the intermediate structure 175 having the graded bandgap energy is formed by adjusting Al concentration during the process of forming the single layer. Alternatively, when the intermediate structure 175 comprises a plurality of layers, each of layers has different compositions in Al, thereby forming the intermediate structure 175 having the graded bandgap energy and is substantially lattice matched with each other. It is noted that, when the intermediate structure 175 having the graded concentrations of Al is a single layer, there is no boundary existing in the single layer. When the intermediate structure 175 has the plurality of layers for achieving the graded concentrations of Al, there is an interface existing between two adjacent layers. In this embodiment, because the intermediate layer 175 and the window layer 176 are n-type, majority carriers are electrons and minority carriers are holes. By virtue of formation the intermediate structure 175 having the bandgap energy between the emitter layer 174 and the window layer 176, a bandgap difference between the emitter layer 174 and the window layer 176 is smoothened and a potential electric field is created such that majority carriers (electrons) in the conductive band are accelerated toward an electron carrier collector, thereby increasing fill factor. Therefore, the photovoltaic device 100 has a fill factor of at least 80% under AM 1.5G irradiation at 500-1000 suns (1 sun=100 mW/cm²).

In this embodiment, the intermediate structure 175 has a thickness less than that of the window layer 176. The intermediate structure 175 has a thickness of 20-40 nm and the window layer 176 has a thickness of 40-60 nm. When the thickness of the intermediate structure 175 is less than 20 nm, a barrier is not effectively formed for holes to flow toward the base layer 172. When the thickness of the intermediate structure 175 is larger than 40 nm, the electrons and holes are easily recombined at interface between the intermediate structure 175 and the emitter layer 174.

The second photovoltaic cell 11 comprises a back-surface field (BSF) layer 151, a base layer 152, an emitter layer 153, and a window layer 154. The third photovoltaic cell 11 comprises a base layer 111 and an emitter layer 112. Each of the first and second tunnel junctions 16, 14 comprises an n-type layer 161, 141 and a p-type layer 162, 142. Each of the n-type layers 141, 161 and the p-type layers 142, 162 of the first and second tunnel junctions 16, 14 comprise GaAs, AlGaAs, InGaP, or AlGaInP. The first tunnel junction 16 has a bandgap energy higher than that of the second photovoltaic cell 15, and the second tunnel junction 14 has a bandgap energy higher than that of the third photovoltaic cell 11. The anti-reflecting coating (ARC) layer 19 comprises a single layer or a multi-layer, and comprises TiO₂ or Al₂O₃.

The emitter layer and the base layer in each photovoltaic cell form a p-n junction therebetween and can convert sun light into electricity. The tunnel junction is heavily doped and has a relatively thin thickness, which is used for providing a low-resistance connection between two adjacent photovoltaic cells and does not convert sun light into electricity. The back-surface field (BSF) layer is used for keeping electrons toward the emitter layer to be reused. The window layer in each photovoltaic cell is to reduce recombination of holes and electrons and is to keep holes to flow toward the base layer.

### Simulation

### Simulation Example (SE)

The first photovoltaic cell 17 (InGaP cell), the second photovoltaic cell 15 (GaAs cell) and the third photovoltaic cell 11 (Ge cell) are subsequently formed. The BSF layer 171 is Zn-doped Al_{0.25}Ga_{0.25}In_{0.5}P, the base layer 171 is Zn-doped Ga_{0.5}In_{0.5}P, the i-type semiconductor layer 173 is Ga_{0.5}In_{0.5}P, the emitter layer 174 is Si-doped Ga_{0.5}In_{0.5}P, the intermediate structure 175 is In_{0.5}(GaₓAl₁₋ₓ)_{0.5}P, 0≦x≦0.25, which has a graded bandgap energy, and the window layer 176 is Si-doped Al_{0.5}In_{0.5}P. The contact layer 18 is Si-doped GaAs. The anti-reflecting coating layer 19 has two sub-layers. One of two sub-layers comprises TiO₂ and the other comprises Al₂O₃. The first contact layer 18 comprises GaAs and the second contact layer 10 comprises NiGeAu.

### Simulation Comparative Example (SCE)

The comparative example has a structure similar to that of Example, except that the first photovoltaic cell 17 (InGaP cell) does not comprises the intermediate layer 175.

TABLE 1

| | Suns | |
|---|---|---|
| | (1sun = 100 mW/cm²) | Fill factor (%) |
| SE | 500 | 84.03 |
| SCE | 500 | 87.23 |
| SE | 1000 | 74.9 |
| SCE | 1000 | 83.56 |

Table 1 shows experimental results of Simulation Example and Simulation Comparative Example. The photovoltaic device of Simulation Example has a fill factor of 87.23%, which is improved as compared to that of Simulation Comparative Example having the fill factor of 84.03% at 500 suns. The photovoltaic device of Simulation Example has a fill factor of 83.56%, which is improved as compared to that of Simulation Comparative Example having the fill factor of 74.9% at 1000 suns. By forming the intermediate layer 175 having a graded bandgap energy, the electrons in the conductive band are accelerated toward an electron carrier collector, thereby increasing fill factor and efficiency of the photovoltaic device.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A photovoltaic device comprising:
a substrate;
a first photovoltaic cell disposed over the substrate comprising
a base layer having a first conductivity type;
an emitter layer on the base layer and having a second conductivity type;
a window layer on the emitter layer and having the second conductivity type; and
an intermediate structure between the emitter layer and the window layer having the second conductivity type, and comprising a first portion adjacent to the emitter layer and a second portion on the first portion;
wherein the first portion comprises a bandgap energy higher than that of the emitter layer and the intermediate structure is substantially lattice matched with the emitter layer.

2. The photovoltaic device of claim 1, wherein the second portion comprises a bandgap energy higher than that of the first portion.

3. The photovoltaic device of claim 1, wherein the intermediate structure is substantially lattice matched with the window layer.

4. The photovoltaic device of claim 1, wherein the window layer has a bandgap energy higher than that of the emitter layer.

5. The photovoltaic device of claim 4, wherein the intermediate structure has a graded bandgap energy increasing along a direction from the emitter layer to the window layer.

6. The photovoltaic device of claim 1, wherein the intermediate structure comprises In_{0.5}(GaₓAl₁₋ₓ)_{0.5}P; wherein x is stepped or continuously variant from the first portion to the second portion.

7. The photovoltaic device of claim 1, wherein each of the intermediate structure and the window layer comprises an impurity.

8. The photovoltaic device of claim 7, wherein a concentration of the impurity of the intermediate structure is higher than that of the window layer.

9. The photovoltaic device of claim 7, wherein the impurity comprises Si, S, or Te.

10. The photovoltaic device of claim 1, wherein the thickness of the intermediate structure is less than that of the window layer.

11. The photovoltaic device of claim 1, wherein a ratio of the thickness of the intermediate structure to the thickness of the window layer ranges from ⅓ to 1.

12. The photovoltaic device of claim 1, wherein the thickness of the intermediate structure is from 20 nm to 40 nm.

13. The photovoltaic device of claim 1, the thickness of the window layer is from 40 nm to 60 nm.

14. The photovoltaic device of claim 1, wherein the fill factor of the photovoltaic device is at least 80% under 1000 suns AM 1.5G condition.

15. The photovoltaic device of claim 1, wherein the first portion is directly contacting the emitter layer and the second portion is directly contacting the window layer.

16. The photovoltaic device of claim 1, further comprising a second photovoltaic cell and a third photovoltaic cell stacked on the first photovoltaic cell, wherein the first photovoltaic cell is a top cell.

17. The photovoltaic device of claim 1, wherein the first conductivity type is p-type, and the second conductivity type is n-type.
